(19) United States
(12) Patent Application Publication
(10) Pub. No.: US 2026/0143812 A1
(43) Pub. Date: May 21, 2026

(54) NITRIDE SEMICONDUCTOR DEVICE

(71) Applicant: ROHM CO., LTD., Kyoto (JP)

(72) Inventor: Takayasu OKA, Kyoto (JP)

(73) Assignee: ROHM CO., LTD., Kyoto (JP)

(21) Appl. No.: 19/447,277

(22) Filed: Jan. 13, 2026

Related U.S. Application Data
(63) Continuation of application No. PCT/JP2024/023790, filed on Jul. 1, 2024.

(30) Foreign Application Priority Data
Jul. 18, 2023 (JP) 2023-116837

(51) Int. Cl. H10D 86/00; H10D 1/00; H10D 1/47; H10D 30/01; H10D 30/47; H10D 62/824; H10D 62/832; H10D 64/23; H10D 86/01

(52) U.S. Cl. CPC H10D 86/00; H10D 1/472; H10D 30/475; H10D 62/824; H10D 62/8325; H10D 64/257; H10D 1/021; H10D 30/015; H10D 86/01

(57) ABSTRACT

This nitride semiconductor device includes: a conductive substrate having a substrate upper surface; a high-resistance layer; a nitride semiconductor layer formed on the high-resistance layer; a first electrode (source electrode) formed on the nitride semiconductor layer; and a via. The high-resistance layer is formed on the substrate upper surface, and has a higher resistance value than does the conductive substrate. The via is electrically connected to the first electrode (source electrode), is provided so as to pass through the nitride semiconductor layer and the high-resistance layer, and contacts the substrate upper surface.

### CROSS-REFERENCE TO RELATED APPLICATIONS

This application is a continuation of, and claims the benefit of priority from International Application No. PCT/JP 2024/023790, filed on Jul. 1, 2024, which claims the benefit of priority from Japanese Patent Application No. 2023-116837, filed on Jul. 18, 2023, the entire contents of each are incorporated herein by reference.

### BACKGROUND

### 1. Field

The following description relates to a nitride semiconductor device.

### 2. Description of Related Art

High-electron-mobility transistors (HEMTs) are now being commercialized. A HEMT uses a group III nitride semiconductor such as gallium nitride (GaN). In the description below, such a semiconductor may be simply referred to as “nitride semiconductor.” A HEMT uses two-dimensional electron gas (2DEG), formed near a semiconductor heterojunction interface, as a conductive path (channel). A power device using a HEMT has a lower ON resistance and is operable at a higher speed and higher frequency than a typical silicon (Si) power device.

JP6877896B discloses an example of a nitride semiconductor device that includes a silicon substrate having an upper surface and a lower surface, an electron transit layer formed on the upper surface of the silicon substrate and composed of a gallium nitride (GaN) layer, and an electron supply layer formed on the electron transit layer and composed of an aluminum gallium nitride (AlGaN) layer. The 2DEG is formed in the electron transit layer near the heterojunction interface of the electron transit layer and the electron supply layer.

### BRIEF DESCRIPTION OF THE DRAWINGS

FIG. 1 is a schematic plan view showing a first embodiment of an exemplary nitride semiconductor device.

FIG. 2 is a cross-sectional view taken along line 2-2 in FIG. 1.

FIG. 3 is a schematic cross-sectional view showing an exemplary manufacturing step of manufacturing the nitride semiconductor device of the first embodiment.

FIG. 4 is a schematic cross-sectional view showing a manufacturing step subsequent to the step shown in FIG. 3.

FIG. 5 is a schematic cross-sectional view showing a manufacturing step subsequent to the step shown in FIG. 4.

FIG. 6 is a schematic cross-sectional view showing a manufacturing step subsequent to the step shown in FIG. 5.

FIG. 7 is a schematic cross-sectional view showing a manufacturing step subsequent to the step shown in FIG. 6.

FIG. 8 is a schematic cross-sectional view showing a manufacturing step subsequent to the step shown in FIG. 7.

FIG. 9 is a schematic cross-sectional view of an exemplary nitride semiconductor device according to a second embodiment.

FIG. 10 is a schematic cross-sectional view showing an exemplary manufacturing step of manufacturing the nitride semiconductor device of the second embodiment.

FIG. 11 is a schematic cross-sectional view showing a manufacturing step subsequent to the step shown in FIG. 10.

FIG. 12 is a schematic cross-sectional view illustrating a manufacturing step subsequent to the step of FIG. 11.

FIG. 13 is a schematic cross-sectional view illustrating a manufacturing step subsequent to the step of FIG. 12.

FIG. 14 is a schematic cross-sectional view showing a manufacturing step subsequent to the step shown in FIG. 13.

FIG. 15 is a schematic cross-sectional view showing a modified example of a manufacturing step subsequent to the step shown in FIG. 3.

FIG. 16 is a schematic cross-sectional view showing a modified example of a manufacturing step subsequent to the step shown in FIG. 15.

FIG. 17 is a schematic cross-sectional view showing a modified example of a manufacturing step subsequent to the step shown in FIG. 16.

FIG. 18 is a schematic cross-sectional view showing a modified example of a manufacturing step subsequent to the step shown in FIG. 17.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Embodiments of a nitride semiconductor device will now be described with reference to the drawings.

In the drawings, components may not be drawn to scale for simplicity and clarity of illustration. To aid understanding, hatching lines may not be shown in the cross-sectional drawings. The accompanying drawings illustrate exemplary embodiments in accordance with the present disclosure and are not intended to limit the present disclosure.

### First Embodiment

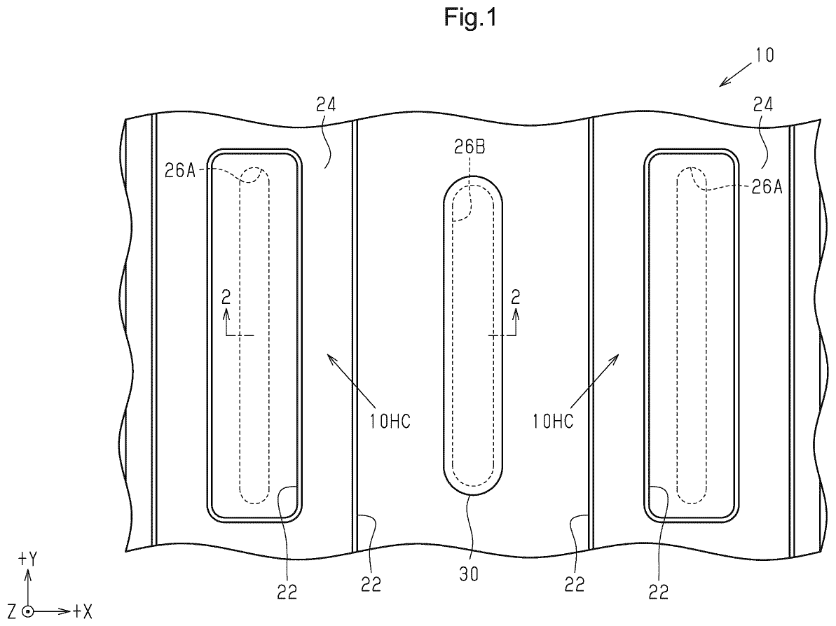

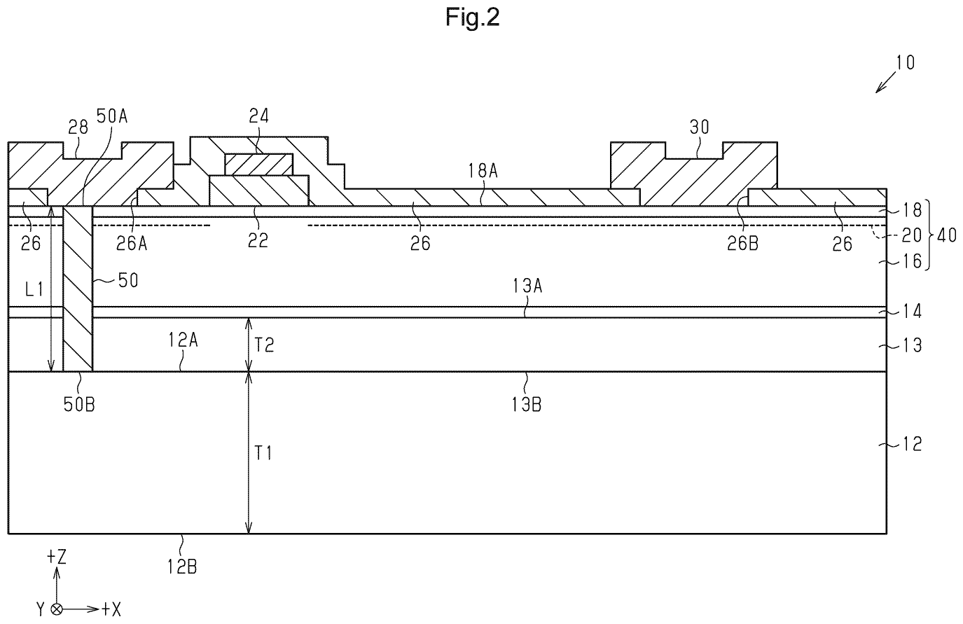

FIG. 1 is a schematic plan view of an exemplary nitride semiconductor device 10 according to one embodiment. FIG. 2 is a schematic cross-sectional view of the nitride semiconductor device 10 taken along line 2-2 in FIG. 1. As shown in FIGS. 1 and 2, the X-axis, Y-axis, and Z-axis are orthogonal to one another. In the present disclosure, the term “plan view” is a view of the nitride semiconductor device 10 taken in the Z-direction. Further, in the nitride semiconductor device 10 shown in FIG. 1, the +Z direction corresponds to the upward direction, the-Z direction corresponds to the downward direction. The +X direction corresponds to the rightward direction, and the-X direction corresponds to the leftward direction. Unless otherwise specified, the term “plan view” will refer to a view of the nitride semiconductor device 10 taken from above along the Z-axis. Also, the term “thickness” will refer to the dimension in the Z-direction unless otherwise specified.

In one example, the nitride semiconductor device 10 may be a high-electron-mobility transistor (HEMT) that uses GaN. The cross-sectional structure of the nitride semiconductor device 10 will now be described with reference to FIG. 2. Then, the planar structure of the nitride semiconductor device 10 will be described with reference to FIG. 1.

As shown in FIG. 2, the nitride semiconductor device 10 includes a conductive substrate 12, a high-resistance layer 13 formed on the conductive substrate 12, a buffer layer 14 formed on the high-resistance layer 13, and a nitride semiconductor layer 40 formed on the buffer layer 14. The buffer layer 14 and the nitride semiconductor layer 40 are epitaxially grown on an upper surface 13A of the high-resistance layer 13. The nitride semiconductor layer 40 includes an electron transit layer 16 formed on the buffer layer 14 and an electron supply layer 18 formed on the electron transit layer 16. Details of the conductive substrate 12 and the high-resistance layer 13 will be described later.

The buffer layer 14 is formed on the upper surface 13A of the high-resistance layer 13. The buffer layer 14 may be arranged between the high-resistance layer 13 and the electron transit layer 16. In an example, the buffer layer 14 may be formed of any material that facilitates epitaxial growth of the electron transit layer 16. The buffer layer 14 may include one or more nitride semiconductor layers. The thickness of the buffer layer 14 (when multiple buffer layers 14 are arranged, the total thickness of the buffer layers 14) is, for example, greater than or equal to 50 nm and less than or equal to 1 μm. The buffer layer 14 may be omitted.

In an example, the buffer layer 14 may include at least one of an aluminum nitride (AlN) layer, an aluminum gallium nitride (AlGaN) layer, and a graded AlGaN layer having different aluminum (Al) compositions. In an example, the buffer layer 14 may be composed of a single AlN layer, a single AlGaN layer, a layer having an AlGaN/GaN superlattice structure, a layer having an AlN/AlGaN superlattice structure, or a layer having an AlN/GaN superlattice structure. To inhibit current leakage of the buffer layer 14, the buffer layer 14 may be partially doped with an impurity so that the buffer layer 14 becomes semi-insulating. In such a case, the impurity may be, for example, carbon (C) or iron (Fe). The concentration of the impurity may be, for example, greater than or equal to 4×10¹⁶ cm⁻³.

The electron transit layer 16 is composed of a nitride semiconductor. The electron transit layer 16 is, for example, a GaN layer. The thickness of the electron transit layer 16 is, for example, greater than or equal to 0.5 μm and less than or equal to 2 μm. To inhibit current leakage of the electron transit layer 16, the electron transit layer 16 may be partially doped with an impurity so that the electron transit layer 16 excluding its surface region becomes semi-insulating. In this case, the impurity is, for example, C. The peak concentration of the impurity in the electron transit layer 16 is, for example, greater than or equal to 1×10¹⁹ cm⁻³.

The electron supply layer 18 is composed of a nitride semiconductor having a bandgap that is larger than that of the electron transit layer 16. The electron supply layer 18 is, for example, an AlGaN layer. In this case, the bandgap becomes larger as the Al composition increases. Thus, the electron supply layer 18, which is an AlGaN layer, has a larger band gap than the electron transit layer 16, which is a GaN layer. In an example, the electron supply layer 18 is composed of AlₓGa₁₋ₓN, where 0.1<x<0.4, and more preferably 0.2<x<0.3. The thickness of the electron supply layer 18 is, for example, greater than or equal to 5 nm and less than or equal to 20 nm.

The electron transit layer 16 and the electron supply layer 18 are composed of nitride semiconductors having different lattice constants. Thus, the nitride semiconductor of the electron transit layer 16 (e.g., GaN) and the nitride semiconductor of the electron supply layer 18 (e.g., AlGaN) form a lattice-mismatched heterojunction. The energy level of the conduction band of the electron transit layer 16 in the vicinity of the heterojunction interface is lower than the Fermi level due to spontaneous polarization of the electron transit layer 16 and the electron supply layer 18 and piezoelectric polarization caused by stress applied to the electron supply layer 18 in the vicinity of the heterojunction interface. As a result, at a location close to the heterojunction interface between the electron transit layer 16 and the electron supply layer 18 (e.g., within range approximately a few nanometers from the interface), two-dimensional electron gas 20 (2DEG) spreads in the electron transit layer 16.

The nitride semiconductor device 10 further includes a gate layer 22 formed on the electron supply layer 18, a gate electrode 24 formed on the gate layer 22, and a passivation layer 26. The passivation layer 26 is formed on the electron supply layer 18, the gate layer 22, and the gate electrode 24 and has a first opening 26A and a second opening 26B. The nitride semiconductor device 10 further includes a source electrode 28, which is in contact with an upper surface 18A of the electron supply layer 18 through the first opening 26A, a drain electrode 30, which is in contact with the upper surface 18A of the electron supply layer 18 through the second opening 26B, and a via 50. Details of the via 50 will be described later.

The gate layer 22 is located between the first opening 26A and the second opening 26B of the passivation layer 26 and is separated from each of the first opening 26A and the second opening 26B. The gate layer 22 is located closer to the first opening 26A than to the second opening 26B. The thickness of the gate layer 22 is, for example, greater than or equal to 100 nm and less than or equal to 200 nm.

The gate layer 22 has a smaller band gap than the electron supply layer 18 and is composed of a nitride semiconductor containing an acceptor impurity. The gate layer 22 may be formed from any material having a smaller band gap than the electron supply layer 18, which is an AlGaN layer. In an example, the gate layer 22 is a GaN layer (p-type GaN layer) doped with an acceptor impurity.

The acceptor impurity may include at least one of magnesium (Mg), zinc (Zn), and C. The acceptor impurity is, for example, Mg. The maximum concentration of the acceptor impurity in the gate layer 22 is, for example, greater than or equal to 1×10¹⁸ cm⁻³ or greater than or equal to 1×10¹⁹ cm⁻³. The maximum concentration of the acceptor impurity in the gate layer 22 is, for example, less than or equal to 1×10²⁰ cm⁻³.

As described above, the acceptor impurity included in the gate layer 22 increases the energy levels of the electron transit layer 16 and the electron supply layer 18. As a result, in a region immediately below the gate layer 22, the energy level of the conduction band of the electron transit layer 16 in the vicinity of the heterojunction interface between the electron transit layer 16 and the electron supply layer 18 is substantially equal to or greater than the Fermi level. Therefore, when no voltage is applied to the gate electrode 24, that is, in the zero bias state, the 2DEG 20 is not formed in the electron transit layer 16 in the region immediately below the gate layer 22. On the other hand, in a region other than the region immediately below the gate layer 22, the 2DEG 20 is formed in the electron transit layer 16.

In this manner, the gate layer 22, which is doped with the acceptor impurity, depletes the 2DEG 20 at the region immediately below the gate layer 22. This results in the transistor being normally off. The application of an appropriate on-voltage to the gate electrode 24 will form a channel with the 2 DEG 20 in the electron transit layer 16 at the region immediately below the gate electrode 24 and electrically connect the source and drain.

The gate electrode 24 is formed of one or more metal layers. In one example, the gate electrode 24 is a titanium nitride (TiN) layer. Alternatively, the gate electrode 24 may be formed of a first metal layer formed from a material containing Ti and a second metal layer formed from a material containing TiN. The gate electrode 24 and the gate layer 22 may form a Schottky junction. The gate electrode 24 may be formed in a region smaller than the gate layer 22 in plan view. The thickness of the gate electrode 24 is, for example, greater than or equal to 50 nm and less than or equal to 200 nm.

The passivation layer 26 is formed on the electron supply layer 18. In other words, the passivation layer 26 covers the upper surface 18A of the electron supply layer 18. The passivation layer 26 may be formed of a material containing one of, for example, silicon nitride (SiN), silicon dioxide (SiO₂), silicon oxynitride (SiON), alumina (Al₂O₃), AlN, and aluminum oxynitride (AlON). In an example, the passivation layer 26 is formed from a material containing SiN. The passivation layer 26 includes portions covering the gate layer 22 and the gate electrode 24 conforming to the surfaces of the gate layer 22 and the gate electrode 24. Thus, the passivation layer 26 has a non-flat surface. The thickness of the passivation layer 26 is, for example, less than or equal to 200 nm. The thickness of the passivation layer 26 may be determined by, for example, the thickness of a portion that is in contact with the electron supply layer 18 or the thickness of a portion that is in contact with the upper surface of the gate electrode 24.

The source electrode 28 and the drain electrode 30 are located at opposite sides of the gate layer 22 in the X-direction on the upper surface 18A of the electron supply layer 18. The source electrode 28 and the drain electrode 30 may be formed of one or more metal layers. For example, the source electrode 28 and the drain electrode 30 may be formed of a combination of two or more metal layers selected from a Ti layer, a TiN layer, an Al layer, an AlSiCu layer, and an AlCu layer. At least a portion of the source electrode 28 fills the first opening 26A. This allows the source electrode 28 to be in ohmic contact with the 2DEG 20, which is located immediately below the electron supply layer 18, through the first opening 26A. Also, at least a portion of the drain electrode 30 fills the second openings 26B. This allows the drain electrode 30 to be in ohmic contact with the 2DEG 20, which is located immediately below the electron supply layer 18, through the second opening 26B.

### Details of the Substrate and the High-Resistance Layer

The conductive substrate 12 includes a substrate upper surface 12A and a substrate lower surface 12B that face in opposite directions. The conductive substrate 12 has a resistance value that is, for example, less than or equal to 2×10⁻² Ωcm. In an example, the conductive substrate 12 is a silicon carbide (SiC) substrate. To obtain low resistance, the conductive substrate 12 may be doped with an impurity. The impurity is, for example, nitrogen (N). Preferably, the conductive substrate 12 is polycrystalline, that is, a polycrystalline SiC substrate. Alternatively, in lieu of a SiC substrate, the conductive substrate 12 may be a silicon (Si) substrate, a GaN substrate, a sapphire substrate, or other semiconductor substrates. Also, in this case, the conductive substrate 12 may be doped with an impurity and may be polycrystalline.

The conductive substrate 12 has a thickness T1 that is, for example, greater than or equal to 50 μm and preferably greater than or equal to 100 μm. The thickness T1 of the conductive substrate 12 is, for example, less than or equal to 500 μm and preferably less than or equal to 350 μm.

The high-resistance layer 13 includes the upper surface 13A and a lower surface 13B that face in opposite directions. The lower surface 13B is a surface of the high-resistance layer 13 facing toward the conductive substrate 12. The high-resistance layer 13 insulates the conductive substrate 12 from the nitride semiconductor layer 40. The high-resistance layer 13 has a higher resistance value than the conductive substrate 12. The resistance value of the high-resistance layer 13 is, for example, greater than or equal to 1×10⁵ Ωcm. In an example in which the buffer layer 14 is arranged, the resistance value of the high-resistance layer 13 is greater than resistance value of the buffer layer 14. When multiple buffer layers 14 are arranged, the resistance value of the high-resistance layer 13 is greater than the total resistance value of the buffer layers 14. In an example in which the buffer layer 14 is not arranged, the resistance value of the high-resistance layer 13 is greater than the resistance value of the electron transit layer 16.

The high-resistance layer 13 may be formed from a semiconductor material such as Si, SiC, GaN, or sapphire. To obtain high resistance, the high-resistance layer 13 may be irradiated with electron beams. The high-resistance layer 13 is, for example, a single-crystal layer. In an example, the high-resistance layer 13 is a single-crystal SiC layer. When the high-resistance layer 13 is a single-crystal SiC layer, the high-resistance layer 13 has, for example, a hexagonal crystal structure and includes an upper surface 13A inclined with respect to the c-plane at an off-angle between 2° and 6°, inclusive. In the present disclosure, the term “c-plane” refers to the (0001) surface of a SiC hexagonal crystal. The off-angle is preferably greater than or equal to 3° and less than or equal to 5°, and more preferably greater than or equal to 3.5° and less than or equal to 4.5°.

Preferably, the thermal expansion coefficient of the high-resistance layer 13 is close to the thermal expansion coefficient of the conductive substrate 12. It is preferred that the difference in thermal expansion coefficient between the conductive substrate 12 and the high-resistance layer 13 is, for example, less than or equal to 1×10⁻⁶ (1/° C.). This configuration limits bending caused by the difference in thermal expansion coefficient between the high-resistance layer 13 and the conductive substrate 12.

To reduce the difference in thermal expansion coefficient, it is preferred, for example, to use a combination of a conductive substrate 12 and a high-resistance layer 13 that are formed of the same type of material. The combination is, for example, a SiC substrate and a SiC layer or a GaN substrate and a GaN layer. In an example of the combination of the conductive substrate 12 and the high-resistance layer 13, the conductive substrate 12 is a polycrystalline SiC substrate, and the high-resistance layer 13 is a single-crystal SiC layer.

The high-resistance layer 13 has a thickness T2 that is, for example, less than or equal to 100 μm and preferably less than or equal to 20 μm. When the thickness T2 of the high-resistance layer 13 is reduced, a length L1 (described later) of the via 50 is reduced. The thickness T2 of the high-resistance layer 13 is, for example, greater than or equal to 3 μm. The thickness T2 of the high-resistance layer 13 is, for example, smaller than the thickness T1 of the conductive substrate 12. Alternatively, the thickness T2 of the high-resistance layer 13 may be greater than the thickness T1 of the conductive substrate 12. The thickness T2 of the high-resistance layer 13 is, for example, smaller than the thickness of the buffer layer 14 (when multiple buffer layers 14 are arranged, the total thickness of the buffer layers 14). Alternatively, the thickness T2 of the high-resistance layer 13 may be greater than the thickness of the buffer layer 14.

### Details of the Via

The via 50 is electrically connected to the source electrode 28 and connects the source electrode 28 to the conductive substrate 12 in the Z-direction. In the present embodiment, the source electrode 28 corresponds to the first electrode. Source voltage is applied to the conductive substrate 12 through the source electrode 28 and the via 50.

The via 50 extends through the layers arranged between the source electrode 28 and the conductive substrate 12 in the Z-direction. More specifically, the via 50 extends through the high-resistance layer 13, the buffer layer 14, the electron transit layer 16, and the electron supply layer 18 in the Z-direction. The via 50 includes a lower end 50B, which is in contact with the substrate upper surface 12A of the conductive substrate 12. The via 50 includes an upper end 50A, which is in contact with the source electrode 28. The shape and size of the via 50 are not particularly limited and may be changed in any manner. The number of vias 50 is not particularly limited. Either a single via 50 or multiple vias 50 may be arranged.

The length L1 of the via 50 is the total thickness (dimension in the Z-direction) of the layers arranged between the source electrode 28 and the conductive substrate 12.

The via 50 may be formed of one or more conductive materials. The conductive material is, for example, a metal material including one or more selected from, for example, Ti, TiN, Au, Ag, Cu, Al, and W. In an example, the via 50 and the source electrode 28 are formed from the same material. In this case, the via 50 and the source electrode 28 may be formed integrally with each other; that is, there is no bonded surface between the via 50 and the source electrode 28.

### Planar Structure of the Nitride Semiconductor Device

The planar structure of the nitride semiconductor device 10 will now be described with reference to FIG. 1. In FIG. 1, the passivation layer 26 and the source electrode 28 are not shown. The first opening 26A and the second opening 26B of the passivation layer 26 are illustrated in broken lines.

The nitride semiconductor device 10 includes, for example, an active region that contributes to operation of a transistor and an inactive region (not shown) that does not contribute to operation of a transistor. In an example, active regions and inactive regions are alternately arranged in the Y-direction.

In the active region of the nitride semiconductor device 10, the source electrode 28 (refer to FIG. 2), the gate electrode 24, and the drain electrode 30 are arranged adjacent to each other in the X-direction on the electron supply layer 18 (refer to FIG. 2). The combination of the source electrode 28, the gate electrode 24, and the drain electrode 30 that are adjacent to each other in the X-direction forms a single HEMT cell 10HC. In the example shown in FIG. 1, two HEMT cells 10HC are arranged in the X-direction in the active region. In an actual structure, a greater number of HEMT cells 10HC may be arranged in each active region.

### Method for Manufacturing the Nitride Semiconductor Device

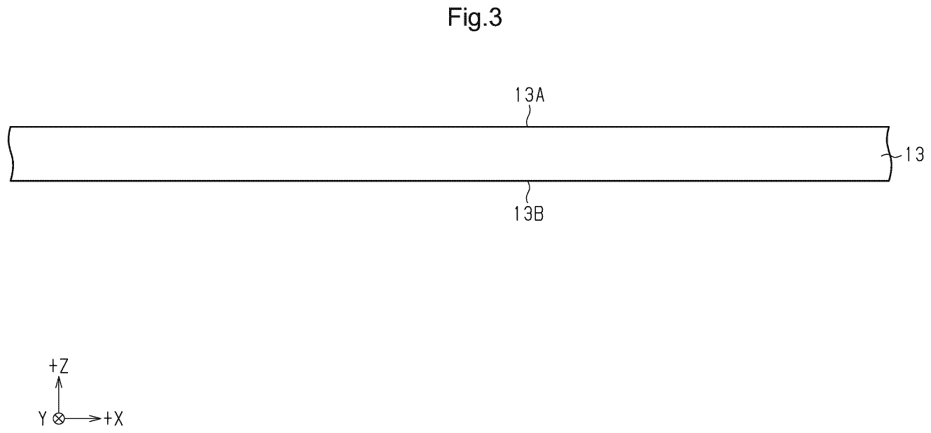

An exemplary method for manufacturing the nitride semiconductor device 10 will now be described with reference to FIGS. 3 to 8. In FIGS. 3 to 8, same reference characters are given to those components that are the same as the corresponding components in FIG. 2.

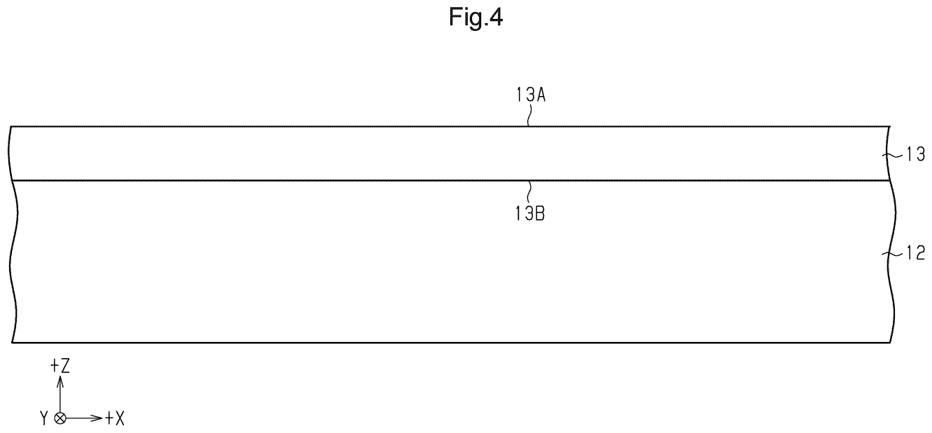

As shown in FIGS. 3 and 4, the method for manufacturing the nitride semiconductor device 10 includes a step of forming the conductive substrate 12 on the lower surface 13B of the high-resistance layer 13. As shown in FIG. 3, a flat member having the upper surface 13A and the lower surface 13B and having a specified thickness is prepared as the high-resistance layer 13. The member described above is, for example, a single-crystal SiC substrate including the upper surface 13A inclined with respect to the c-plane by an off-angle between 2° and 6°, inclusive. The resistance value of the member is greater than or equal to 1×10⁵ Ωcm. The conductive substrate 12 is, for example, a polycrystalline SiC substrate.

In an example, the conductive substrate 12 is formed of a film produced on the high-resistance layer 13 through chemical vapor deposition (CVD). In this case, it is preferred that a specified SiC layer formed through a specified process be used as the high-resistance layer 13, which is used in the method for manufacturing the nitride semiconductor device 10. Specifically, under the presence of a gaseous substance containing an inert gas, an SiC film is formed on a layer including one or both of graphene and hexagonal boron nitride arranged on a substrate. Then, the SiC film is separated from the substrate. The separated SiC film is used as the high-resistance layer 13, and a SiC layer is produced on the surface of the SiC film to form the conductive substrate 12.

In another example, the conductive substrate 12 is formed by bonding a semiconductor layer, which will become the conductive substrate 12, to the lower surface 13B of the high-resistance layer 13. For example, the lower surface 13B of the high-resistance layer 13 is irradiated with a specific impurity in a vacuum. Also, the surface of a semiconductor layer that will become the conductive substrate 12 is irradiated with a specific impurity in a vacuum. Then, in the same vacuum atmosphere in which the irradiation with the specific impurity has been performed, the lower surface 13B of the high-resistance layer 13 and the surface of the semiconductor layer are bonded together and then are heated. The specific impurity is an inert impurity that does not produce carriers in the high-resistance layer 13 and the semiconductor layer. The temperature of the heating process may be determined in accordance with the materials forming the high-resistance layer 13 and the semiconductor layer that will become the conductive substrate 12. For example, when each of the high-resistance layer 13 and the semiconductor layer that will become the conductive substrate 12 is formed of SiC, the temperature of the heating process is greater than or equal to 1500° C. In an example, the temperature of the heating process is approximately 1700° C.

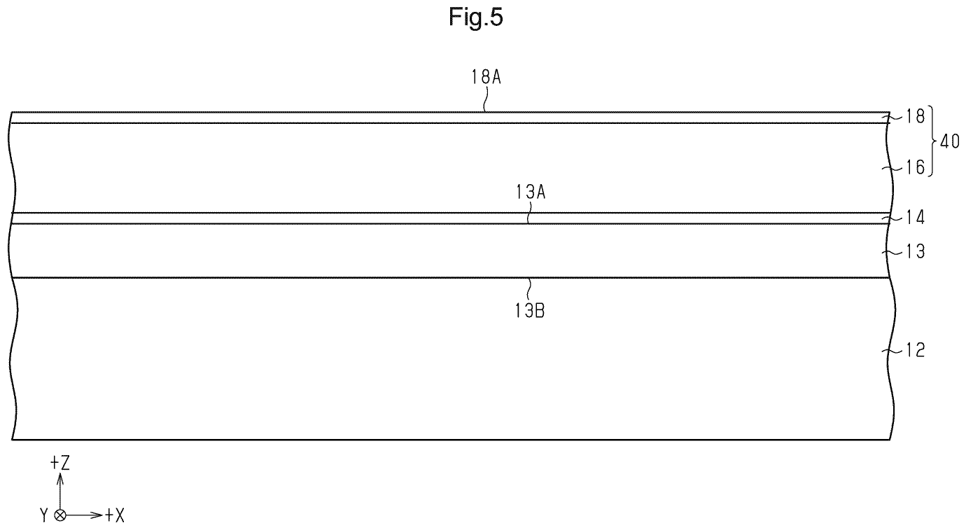

As shown in FIG. 5, the method for manufacturing the nitride semiconductor device 10 includes a step of forming the buffer layer 14 and the nitride semiconductor layer 40 on the high-resistance layer 13.

The electron transit layer 16 and the electron supply layer 18, which are the nitride semiconductor layer 40, and the buffer layer 14 are formed on the upper surface 13A of the high-resistance layer 13. The electron transit layer 16 is formed on the buffer layer 14. The electron supply layer 18 is formed on the electron transit layer 16.

The buffer layer 14, the electron transit layer 16, and the electron supply layer 18 may be epitaxially grown on the high-resistance layer 13 through metal organic chemical vapor deposition (MOCVD). The layers described above are formed from nitride semiconductors having lattice constants relatively close to each other. This allows for sequential epitaxial growth of the layers.

The buffer layer 14 is, for example, multilayered. An AlN layer (first buffer layer) is formed on the high-resistance layer 13, and then a graded AlGaN layer (second buffer layer) is formed on the AlN layer. In an example, the graded AlGaN layer may be formed by stacking three AlGaN layers having Al compositions of 75%, 50%, and 25%, respectively, from the side closest to the AlN layer.

The electron transit layer 16 and the electron supply layer 18 are sequentially formed on the buffer layer 14. During the epitaxial growth of the electron transit layer 16 and the electron supply layer 18, a doping gas may be introduced into the growth chamber if appropriate. This allows for the doping of a desired layer with an impurity. In an example, during the epitaxial growth of the electron supply layer 18, the electron supply layer 18 is doped with Si, which is an n-type impurity. This forms the electron supply layer 18 containing the n-type impurity.

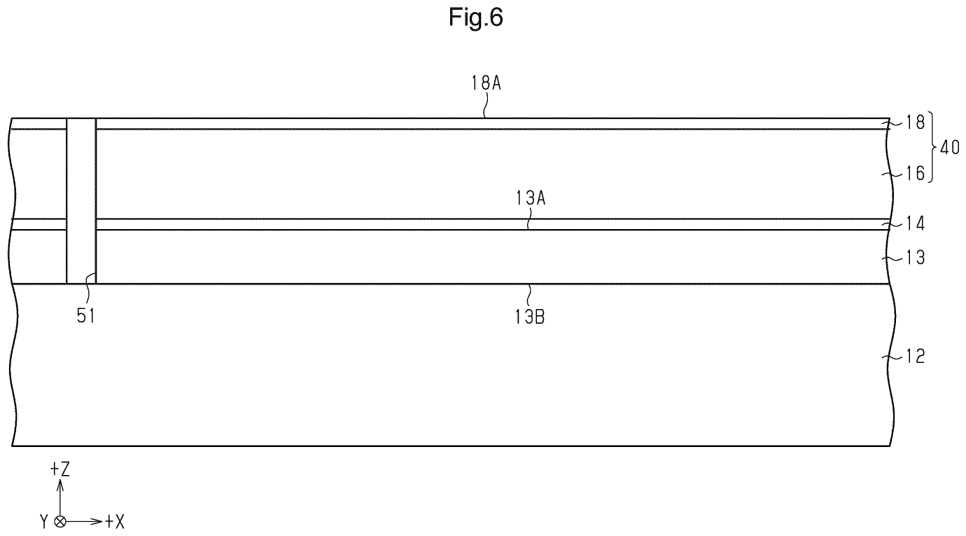

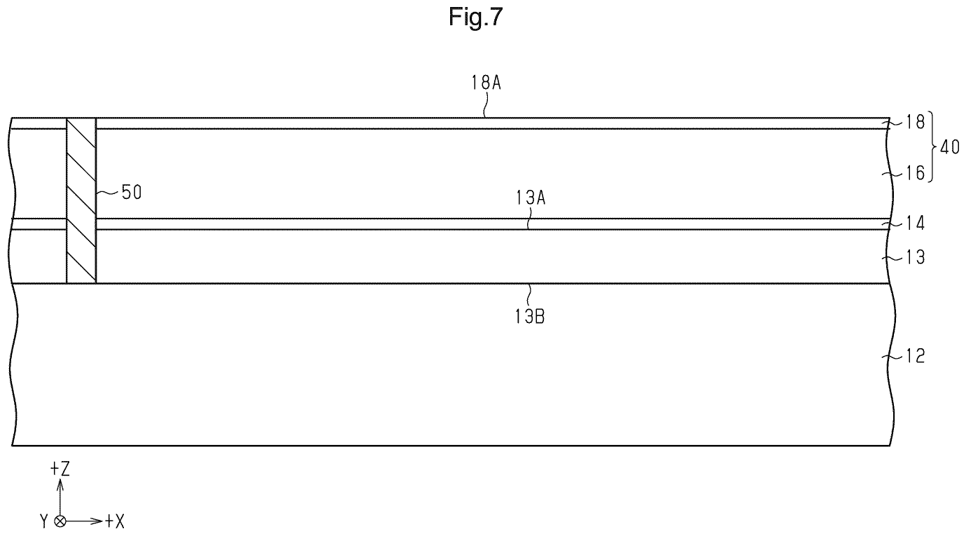

As shown in FIGS. 6 and 7, the method for manufacturing the nitride semiconductor device 10 includes a step of forming the via 50 in the high-resistance layer 13, the buffer layer 14, and the nitride semiconductor layer 40. The step of forming the via 50 includes a step of forming a through hole 51 that extends through the high-resistance layer 13, the buffer layer 14, and the nitride semiconductor layer 40 and a step of filling the through hole 51 with a conductive material.

As shown in FIG. 6, the through hole 51 extends through the high-resistance layer 13, the buffer layer 14, and the nitride semiconductor layer 40 and is open in the upper surface of the nitride semiconductor layer 40 (the upper surface 18A of the electron supply layer 18) and the lower surface 13B of the high-resistance layer 13. In an example, the through hole 51 is formed by grinding the high-resistance layer 13, the buffer layer 14, and the nitride semiconductor layer 40. In another example, the through hole 51 is formed by selectively removing a portion of the high-resistance layer 13, the buffer layer 14, and the nitride semiconductor layer 40 through lithography and etching. The through hole 51 is formed from the side where the upper surface of the nitride semiconductor layer 40 (the upper surface 18A of the electron supply layer 18) is located. The upper surface of the conductive substrate 12 is exposed in the through hole 51. As shown in FIG. 7, a conductive material fills the through hole 51 to form the via 50.

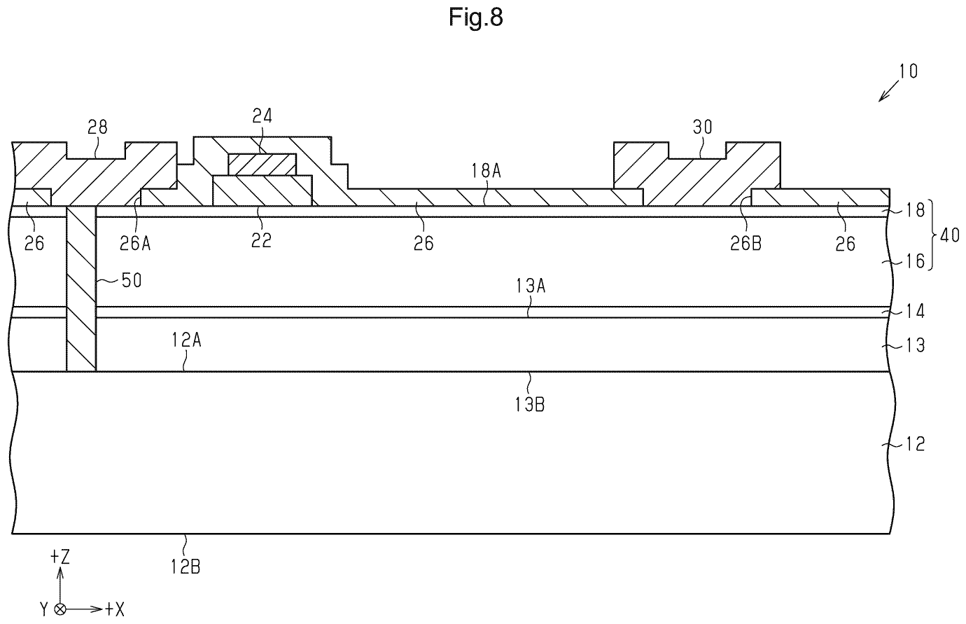

As shown in FIG. 8, the method for manufacturing the nitride semiconductor device 10 includes a step of forming the gate layer 22, a step of forming the gate electrode 24, a step of forming the passivation layer 26, a step of forming the source electrode 28, and a step of forming the drain electrode 30. In the present embodiment, the step of forming the source electrode 28 corresponds to a step of forming the first electrode on the nitride semiconductor layer 40.

The gate layer 22 is formed by selectively removing a nitride semiconductor layer (not shown) formed on the electron supply layer 18 through lithography and etching. The nitride semiconductor layer described above may be epitaxially grown on the electron supply layer 18 through MOCVD. During the epitaxial growth of the nitride semiconductor layer, a doping gas is introduced into the growth chamber. In an example, during the epitaxial growth of the nitride semiconductor layer described above, the nitride semiconductor layer is doped with Mg, which is an acceptor impurity. This forms the gate layer 22 containing the acceptor impurity.

The gate electrode 24 is formed on the gate layer 22. In an example, the gate electrode 24 is formed by selectively removing a metal layer (not shown) formed on the nitride semiconductor layer 40 through lithography and etching.

The passivation layer 26 is formed on the electron supply layer 18, the gate layer 22, and the gate electrode 24. The passivation layer 26 covers a portion of the electron supply layer 18, the gate layer 22, and the gate electrode 24. In an example, the passivation layer 26 may be formed by low-pressure chemical vapor deposition (LPCVD).

The passivation layer 26 has the first opening 26A, which exposes the electron supply layer 18 and the via 50, and the second opening 26B, which exposes the electron supply layer 18. The first opening 26A and the second opening 26B are formed so that the gate layer 22 is arranged between the first opening 26A and the second opening 26B. The first opening 26A and the second opening 26B are formed by selectively etching a portion of the passivation layer 26 through lithography and etching.

The source electrode 28 is formed to be in contact with the upper end 50A of the via 50, and the upper surface 18A of the electron supply layer 18 that is exposed in the first opening 26A of the passivation layer 26. The drain electrode 30 is in contact with the upper surface 18A of the electron supply layer 18 that is exposed in the second opening 26B of the passivation layer 26. In an example, the source electrode 28 and the drain electrode 30 are formed by selectively removing a metal layer (not shown) that covers the passivation layer 26 through lithography and etching. The steps described above obtain the nitride semiconductor device 10.

### Operation

The nitride semiconductor device 10 of the first embodiment will now be described.

In the nitride semiconductor device 10, the resistance value of the conductive substrate 12 is relatively low. Thus, the conductive substrate 12 is used as a back surface electrode to which source voltage is applied from the source electrode 28 and the via 50. The high-resistance layer 13 is used as an insulation layer that insulates the conductive substrate 12 from the nitride semiconductor layer 40 and a HEMT formed of the nitride semiconductor layer 40. With this structure, the via 50 does not need to extend through the conductive substrate 12 and may be in contact with the conductive substrate 12. Therefore, as compared with a typical structure in which a back surface electrode is separately arranged on the lower surface of a substrate, the length L1 of the via 50 is reduced by an amount corresponding to the thickness of the conductive substrate 12. The reduction in the length L1 of the via 50 reduces costs such as the amount of work and time needed to form the via 50.

In addition, in the nitride semiconductor device 10, stress of the nitride semiconductor layer 40, in particular, force acting to bend the nitride semiconductor device 10, is received by the conductive substrate 12 and the high-resistance layer 13. With this structure, even when the thickness of the high-resistance layer 13 is reduced in order to reduce the length L1 of the via 50, the strength to counteract the stress of the nitride semiconductor layer 40 is readily obtained.

### Advantages

The nitride semiconductor device 10 of the first embodiment has the following advantages.
(1-1) The nitride semiconductor device 10 includes the conductive substrate 12 including the substrate upper surface 12A, the high-resistance layer 13, the nitride semiconductor layer 40 formed on the high-resistance layer 13, and a first electrode (the source electrode 28) formed on the nitride semiconductor layer 40, and the via 50. The high-resistance layer 13 is formed on the substrate upper surface 12A and has a higher resistance value than the conductive substrate 12. The via 50 extends through the nitride semiconductor layer 40 and the high-resistance layer 13. Also, the via 50 is electrically connected to the first electrode (the source electrode 28) and is in contact with the substrate upper surface 12A.

With this structure, the length L1 of the via 50 is reduced by the amount corresponding to the thickness of the conductive substrate 12 as compared with a typical structure in which a back surface electrode is separately arranged on the lower surface of a substrate. The reduction in the length L1 of the via 50 reduces costs such as the amount of work and time needed to form the via 50. In addition, the reduction in the length L1 of the via 50 decreases the portion of the via 50 that contacts the high-resistance layer 13 and the nitride semiconductor layer 40. This reduces the ground inductance of the via 50. Accordingly, deterioration of the nitride semiconductor device 10 is limited.
(1-2) The difference in thermal expansion coefficient between the conductive substrate 12 and the high-resistance layer 13 is less than or equal to 1×10⁻⁶ (1/° C.). This configuration limits bending caused by the difference in thermal expansion coefficient between the high-resistance layer 13 and the conductive substrate 12.
(1-3) The thickness T2 of the high-resistance layer 13 is less than the thickness (T1) of the conductive substrate 12. With this structure, the length of the via 50 extending through the high-resistance layer 13 in the thickness-wise direction is reduced. The advantage (1-1) is obtained more prominently.
(1-4) The high-resistance layer 13 includes the upper surface 13A facing toward the nitride semiconductor layer 40. The high-resistance layer 13 is a single-crystal SiC layer having a hexagonal crystal structure. The upper surface 13A of the high-resistance layer 13 is inclined with respect to the c-plane by an off-angle between 2° and 6°, inclusive. SiC substrates are generally expensive. Therefore, the manufacturing cost of a nitride semiconductor device using a SiC substrate may be relatively high. Among the SiC substrates, a SiC substrate having an off-angle is relatively inexpensive.

### Second Embodiment

A second embodiment of a nitride semiconductor device 100 differs from the first embodiment in the structures of a substrate 120, the high-resistance layer 130, and a via 500. The nitride semiconductor device 100 of the second embodiment includes a second electrode 60. Otherwise, the structure is the same as the first embodiment. Such components will not be described in detail below. Components differing from those of the first embodiment will be described.

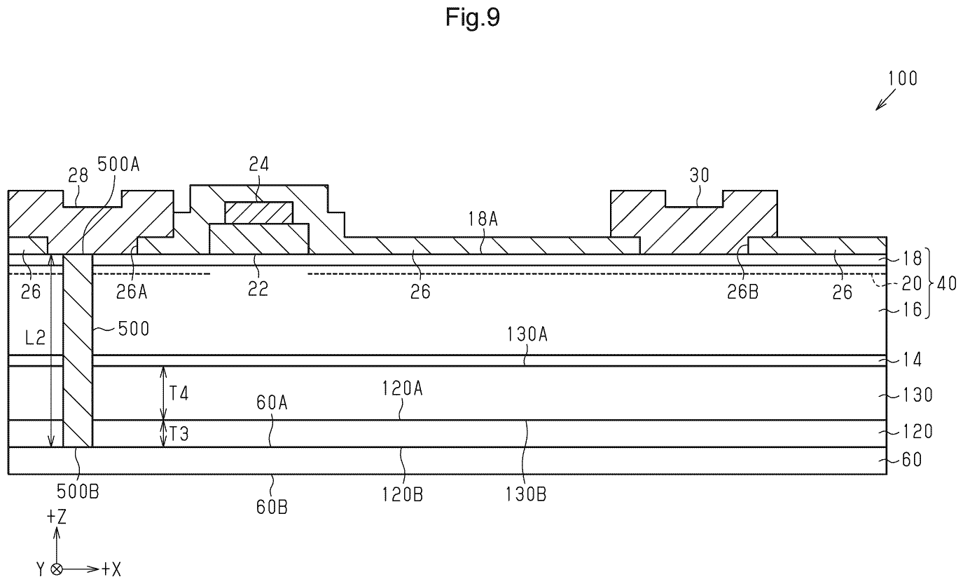

As shown in FIG. 9, the substrate 120 includes a substrate upper surface 120A and a substrate lower surface 120B that face in opposite directions. The substrate 120 differs from the conductive substrate 12 of the first embodiment in configurations related to conductivity and thickness but otherwise has the same configuration as the conductive substrate 12.

The substrate 120 may have conductivity or no conductivity. For example, the resistance value of the substrate 120 may be less than or equal to 2×10⁻² Ωcm or may be greater than 2×10⁻² Ωcm. The substrate 120 is, for example, a semiconductor substrate such as a Si substrate, a SiC substrate, a GaN substrate, and a sapphire substrate. The substrate 120 has a thickness T3 that is, for example, greater than or equal to 1 μm and preferably greater than or equal to 3 μm. The substrate 120 has a thickness T3 that is, for example, less than or equal to 50 μm and preferably less than or equal to 10 μm. When the thickness T3 of the substrate 120 is reduced, a length L2 (described later) of the via 500 is reduced.

The high-resistance layer 130 includes an upper surface 130A and a lower surface 130B that face in opposite directions. The lower surface 130B is a surface of the high-resistance layer 130 facing toward the substrate 120. The high-resistance layer 130 has a higher resistance value than the substrate 120. The resistance value of the high-resistance layer 130 is, for example, greater than or equal to 1×10⁵ Ωcm. When the buffer layer 14 is used, the resistance value of the high-resistance layer 130 is, for example, greater than the resistance value of the buffer layer 14. When multiple buffer layers 14 are arranged, the resistance value of the high-resistance layer 130 is higher than the total resistance value of the buffer layers 14. When the buffer layer 14 is not arranged, the resistance value of the high-resistance layer 130 is, for example, higher than the resistance value of the electron transit layer 16.

The high-resistance layer 130 has a thickness T4 that is, for example, greater than or equal to 3 μm and preferably greater than or equal to 5 μm. The high-resistance layer 130 has a thickness T4 that is, for example, less than or equal to 100 μm and preferably less than or equal to 20 μm. When the thickness T4 of the high-resistance layer 130 is reduced, a length L2 (described later) of the via 500 is reduced. In an example, the thickness T4 of the high-resistance layer 130 is greater than the thickness T3 of the substrate 120. Alternatively, the thickness T4 of the high-resistance layer 130 may be less than the thickness T3 of the substrate 120. In an example, the thickness T4 of the high-resistance layer 130 is greater than the thickness of the buffer layer 14. Alternatively, the thickness T4 of the high-resistance layer 130 may be less than the thickness of the buffer layer 14.

The sum of the thickness T3 of the substrate 120 and the thickness T4 of the high-resistance layer 130 is, for example, greater than or equal to 4 μm and preferably greater than or equal to 8 μm. The sum of the thickness T3 of the substrate 120 and the thickness T4 of the high-resistance layer 130 is, for example, less than or equal to 150 μm and preferably less than or equal to 30 μm. Otherwise, the high-resistance layer 130 has the same configuration as the high-resistance layer 13 of the first embodiment.

The second electrode 60 is formed on the substrate lower surface 120B of the substrate 120. The second electrode 60 includes an upper surface 60A and a lower surface 60B that face in opposite directions. The upper surface 60A of the second electrode 60 faces toward the substrate 120. The second electrode 60 is electrically connected to the source electrode 28 by the via 500 (described later).

The second electrode 60 may be formed of one or more metal layers. In an example, the second electrode 60 may be formed of a combination of two or more metal layers selected from a Ti layer, a TiN layer, an Au layer, an Al layer, an AlSiCu layer, and an AlCu layer. The thickness of the second electrode 60 is, for example, greater than or equal to 3 μm and less than or equal to 50 μm.

The via 500 is electrically connected to the source electrode 28 and connects the source electrode 28 and the second electrode 60 in the Z-direction. Source voltage is applied to the second electrode 60 through the source electrode 28 and the via 50. The via 500 extends through the layers arranged between the source electrode 28 and the second electrode 60 in the Z-direction.

More specifically, the via 500 extends through the substrate 120, the high-resistance layer 130, the buffer layer 14, the electron transit layer 16, and the electron supply layer 18 in the Z-direction. The via 500 includes a lower end 500B, which is in contact with the upper surface 60A of the second electrode 60. The via 500 includes an upper end 500A, which is in contact with the source electrode 28. The shape and size of the via 500 are not particularly limited and may be changed in any manner. The number of vias 500 is not particularly limited. Either a single via 500 or multiple vias 500 may be arranged.

The length L2 of the via 500 is the total thickness (dimension in the Z-direction) of the layers arranged between the source electrode 28 and the second electrode 60.

The configuration related to the material forming the via 500 is the same as that of the via 50 of the first embodiment. In an example, the via 500 is formed from the same material as that of one or both of the source electrode 28 and the second electrode 60. In this case, the via 500 may be formed integrally with one or both of the source electrode 28 and the second electrode 60, which are formed from the same material as that of the via 500. That is, the via 500 does not have a bonded surface with the one or both of the source electrode 28 and the second electrode 60 integrally formed with the via 500.

### Method for Manufacturing the Nitride Semiconductor Device

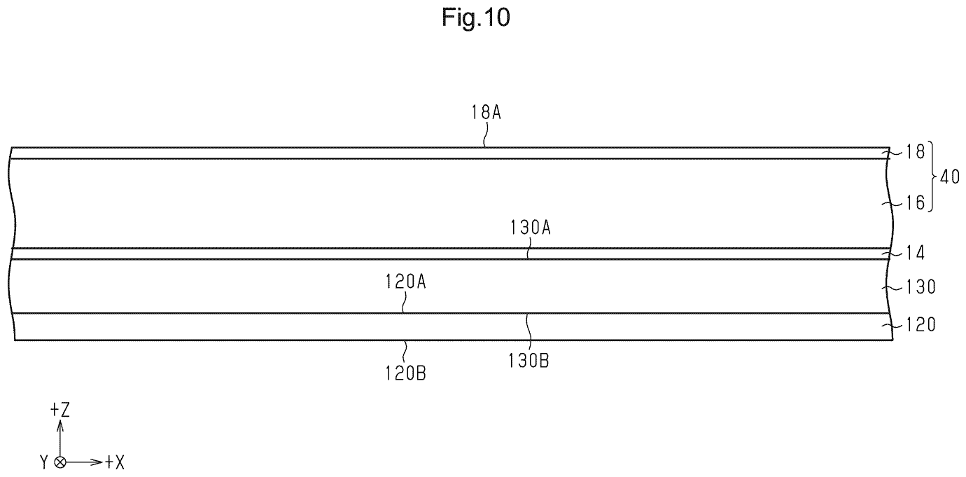

An exemplary method for manufacturing the nitride semiconductor device 100 will now be described with reference to FIGS. 10 to 14. In FIGS. 10 to 14, same reference characters are given to those components that are the same as the corresponding components in FIG. 9.

The method for manufacturing the nitride semiconductor device 100 includes a step of forming the buffer layer 14 and the nitride semiconductor layer 40 on the high-resistance layer 130. This step differs from that of the first embodiment in that the high-resistance layer 13 is changed to the high-resistance layer 130 but otherwise is the same.

As shown in FIG. 10, the method for manufacturing the nitride semiconductor device 100 includes a step of forming the substrate 120 on the lower surface 130B of the high-resistance layer 130. The process for forming the substrate 120 is the same as the process for forming the conductive substrate 12 of the first embodiment. The thickness of the substrate 120 is relatively easily adjusted. Therefore, it is preferred that the substrate 120 be formed of a film produced through CVD.

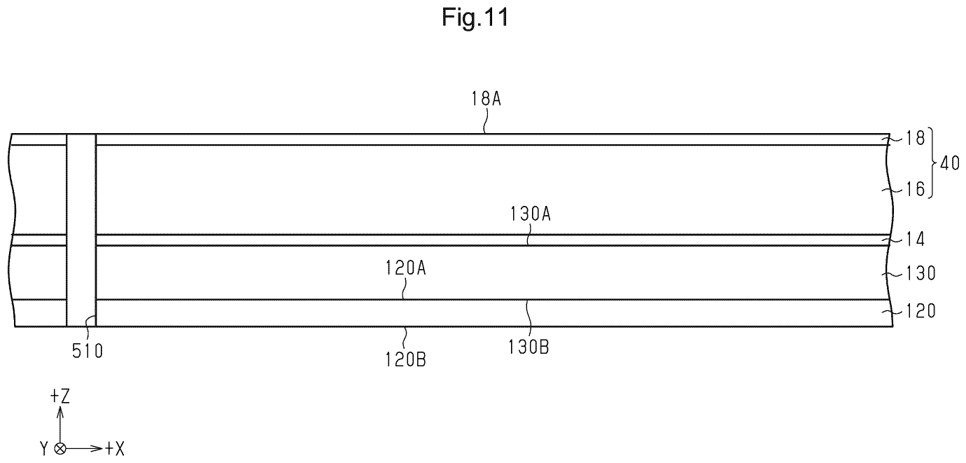

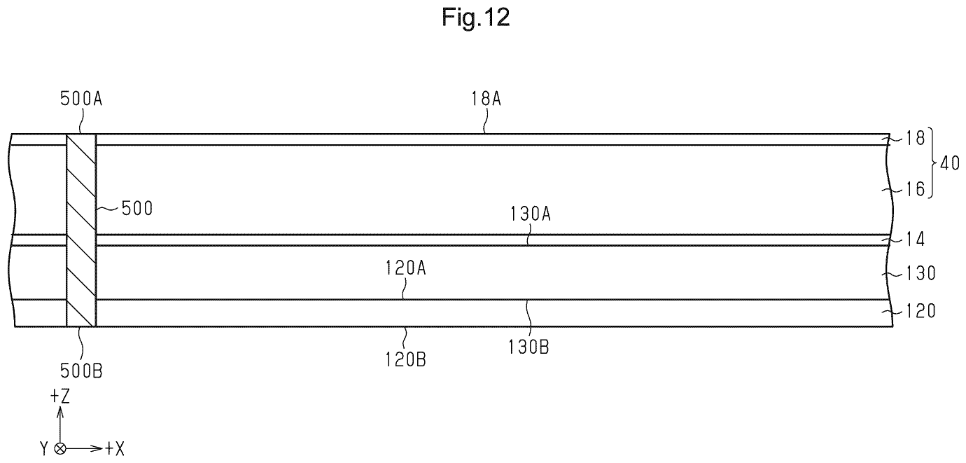

As shown in FIGS. 11 and 12, the method for manufacturing the nitride semiconductor device 100 includes a step of forming the via 500 in the substrate 120, the high-resistance layer 130, the buffer layer 14, and the nitride semiconductor layer 40. The step of forming the via 500 includes a step of forming a through hole 510 that extends through the substrate 120, the high-resistance layer 130, the buffer layer 14, and the nitride semiconductor layer 40 and a step of filling the through hole 510 with a conductive material.

As shown in FIG. 11, the through hole 510 extends through the substrate 120, the high-resistance layer 130, the buffer layer 14, and the nitride semiconductor layer 40 and is open in the upper surface of the nitride semiconductor layer 40 (the upper surface 18A of the electron supply layer 18) and the substrate lower surface 120B of the substrate 120. In an example, the through hole 510 is formed by grinding the substrate 120, the high-resistance layer 130, the buffer layer 14, and the nitride semiconductor layer 40. In another example, the through hole 510 is formed by selectively removing a portion of the substrate 120, the high-resistance layer 130, the buffer layer 14, and the nitride semiconductor layer 40 through lithography and etching. The through hole 510 may be formed from the side where the substrate lower surface 120B of the substrate 120 is located. Alternatively, the through hole 510 may be formed from the side where the upper surface of the nitride semiconductor layer 40 (the upper surface 18A of the electron supply layer 18) is located. As shown in FIG. 12, a conductive material fills the through hole 510 to form the via 500.

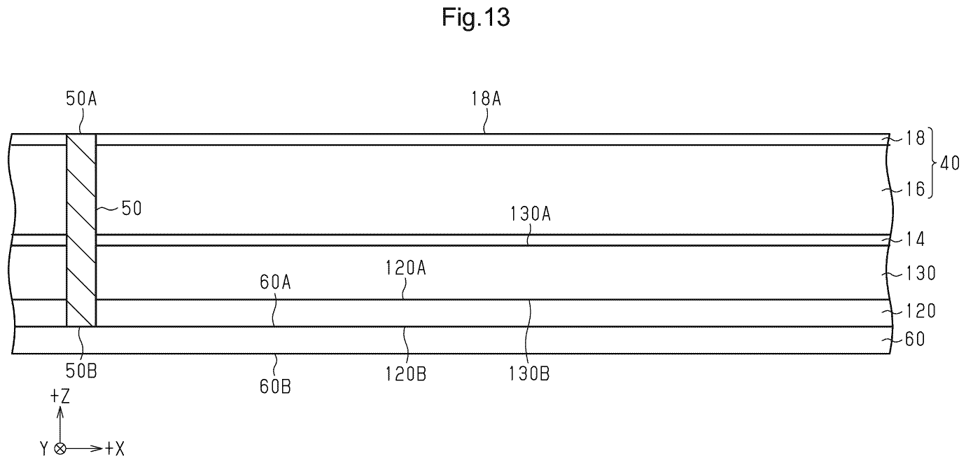

As shown in FIG. 13, the method for manufacturing the nitride semiconductor device 100 includes a step of forming the second electrode 60 on the substrate lower surface 120B of the substrate 120. In an example, a metal layer is formed on the substrate lower surface 120B of the substrate 120 and is used as the second electrode 60.

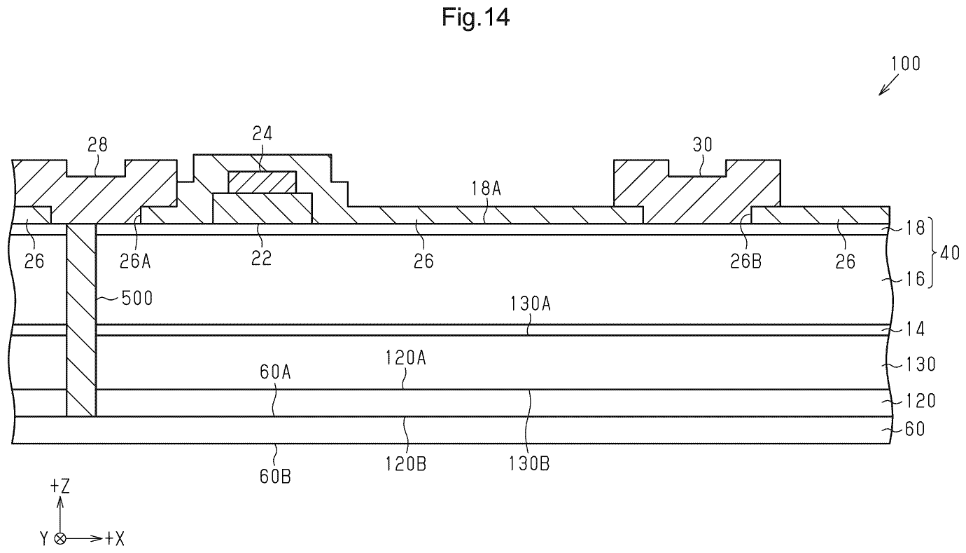

As shown in FIG. 14, the method for manufacturing the nitride semiconductor device 100 includes a step of forming the gate layer 22, a step of forming the gate electrode 24, a step of forming the passivation layer 26, a step of forming the source electrode 28, and a step of forming the drain electrode 30. Each step described above is the same as that of the first embodiment. The steps described above obtain the nitride semiconductor device 100.

### Operation

The operation of the nitride semiconductor device 100 according to the second embodiment will now be described.

In the nitride semiconductor device 100, the substrate 120 and the high-resistance layer 130 are arranged between the nitride semiconductor layer 40 and the second electrode 60, which is connected to the source electrode 28 through the via 500. The via 500 extends through the substrate 120 and the high-resistance layer 130. With this structure, the thickness (hereafter, will be referred to as “inter-layer thickness”) of a layer arranged between the second electrode 60 and the nitride semiconductor layer 40 is readily adjusted as compared with a typical structure in which only a substrate having a high resistance value is arranged between the second electrode 60 and the nitride semiconductor layer 40.

More specifically, in the typical structure in which only a substrate having a high resistance value is arranged between the second electrode 60 and the nitride semiconductor layer 40, a substrate having a thickness that is greater than the specified inter-layer thickness is used to form the nitride semiconductor layer 40 and a HEMT formed of the nitride semiconductor layer 40. Subsequently, the substrate is cut to have a predetermined inter-layer thickness. That is, the inter-layer thickness is adjusted by cutting the substrate.

In the nitride semiconductor device 100, the substrate 120 having a second specified thickness is bonded to the lower surface 130B of the high-resistance layer 130 having a first specified thickness. Alternatively, a film having the second specified thickness is produced to form the substrate 120. Thus, the inter-layer thickness (first specified thickness +second specified thickness) is adjusted by newly forming the substrate 120. When the substrate 120 is newly formed to adjust the inter-layer thickness, the amount of work and time are reduced as compared with when the substrate is cut to adjust the inter-layer thickness. This reduces the costs for manufacturing the nitride semiconductor device 100 having the via 500.

### Advantages

The nitride semiconductor device 100 of the second embodiment has the advantages (1-2) and (1-3) described above. Additionally, the nitride semiconductor device 100 of the second embodiment has the advantages described below.
(2-1) The nitride semiconductor device 100 includes the substrate 120 including the substrate upper surface 120A and the substrate lower surface 120B, the high-resistance layer 130, the nitride semiconductor layer 40 formed on the high-resistance layer 130, the source electrode 28 formed on the nitride semiconductor layer 40, the second electrode 60 formed on the substrate lower surface 120B of the substrate 120, and the via 500. The high-resistance layer 130 is formed on the substrate upper surface 120A and has a higher resistance value than the substrate 120. The via 500 extends through the nitride semiconductor layer 40, the high-resistance layer 130, and the substrate 120. The via 500 is electrically connected to the source electrode 28 and the second electrode 60. With this structure, the costs for adjusting the thickness (inter-layer thickness) of layers arranged between the second electrode 60 and the nitride semiconductor layer 40 is reduced as compared with a typical structure in which only a substrate having a high resistance value is arranged between the second electrode 60 and the nitride semiconductor layer 40.
(2-2) The thickness T4 of the high-resistance layer 130 is greater than the thickness T3 of the substrate 120. In this case, the time taken to produce a film on the lower surface 130B of the high-resistance layer 130 to form the substrate 120 is further shortened. Therefore, the advantage (2-1) is obtained more prominently.

### MODIFIED EXAMPLES

The embodiments may be modified, for example, as follows. The above embodiments and the modified examples described below may be combined as long as there is no technical contradiction. In the modified examples described hereafter, same reference characters are given to those components that are the same as the corresponding components of the above embodiments. Such components will not be described in detail.

In the nitride semiconductor device 10 of the first embodiment, the first electrode that is connected to the conductive substrate 12 by the via 50 is not limited to the source electrode 28. For example, the via 50 may electrically connect the drain electrode 30 and the conductive substrate 12. In this case, the first electrode is the drain electrode 30. Also, in this case, drain voltage is applied to the conductive substrate 12 through the drain electrode 30 and the via 50. The via 500 in the nitride semiconductor device 100 of the second embodiment may be modified in the same manner.

The nitride semiconductor device 10 of the first embodiment may be of a normally-on type that does not include the gate layer 22. The nitride semiconductor device 100 of the second embodiment may be modified in the same manner.

In the nitride semiconductor device 10 of the first embodiment, the conductive substrate 12 may include a metal substrate instead of a semiconductor substrate. In this case, the conductive substrate 12 is, for example, a Cu substrate, a molybdenum (Mo) substrate, a tantalum (Ta) substrate, a Ti substrate, a niobium (Nb) substrate, or a compound substrate including one or more of these substrates.

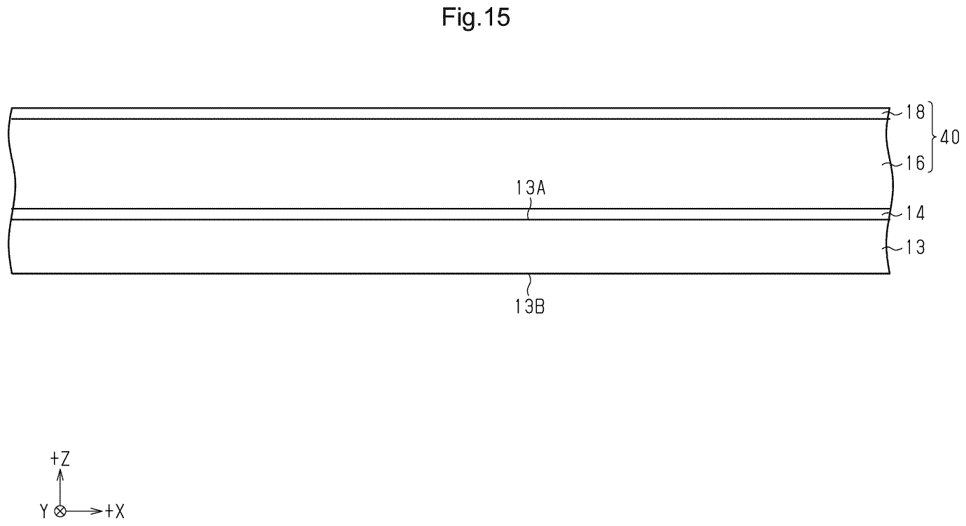

In the method for manufacturing the nitride semiconductor device 10 of the first embodiment, the sequence of the steps is not limited to that described in the embodiment and may be changed in any manner. For example, the nitride semiconductor device 10 may be manufactured in the sequence shown in FIGS. 15 to 18.

FIG. 15 shows a step performed subsequent to the step shown in FIG. 3 for forming the buffer layer 14 and the nitride semiconductor layer 40 on the high-resistance layer 13. As shown in FIG. 15, the electron transit layer 16 and the electron supply layer 18, which are the nitride semiconductor layer 40, and the buffer layer 14 are formed on the upper surface 13A of the high-resistance layer 13.

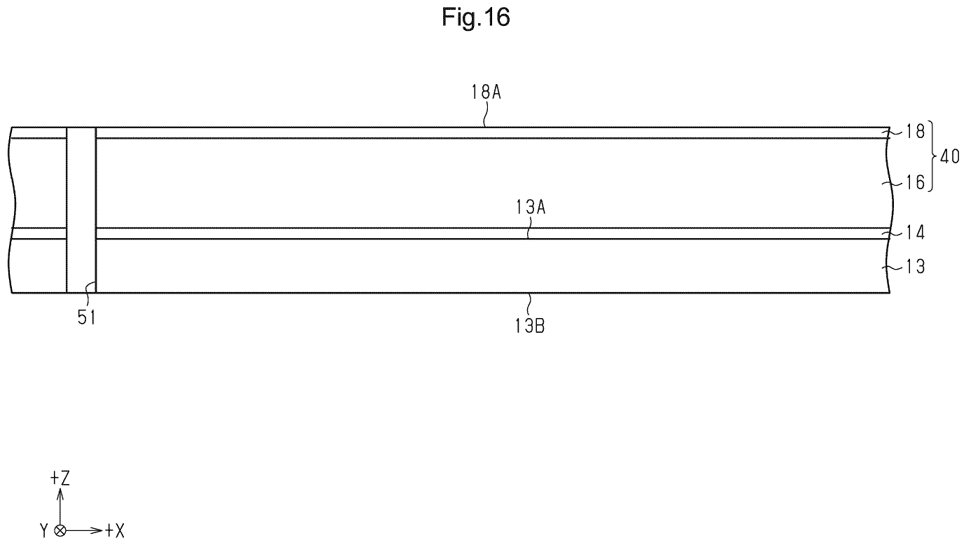

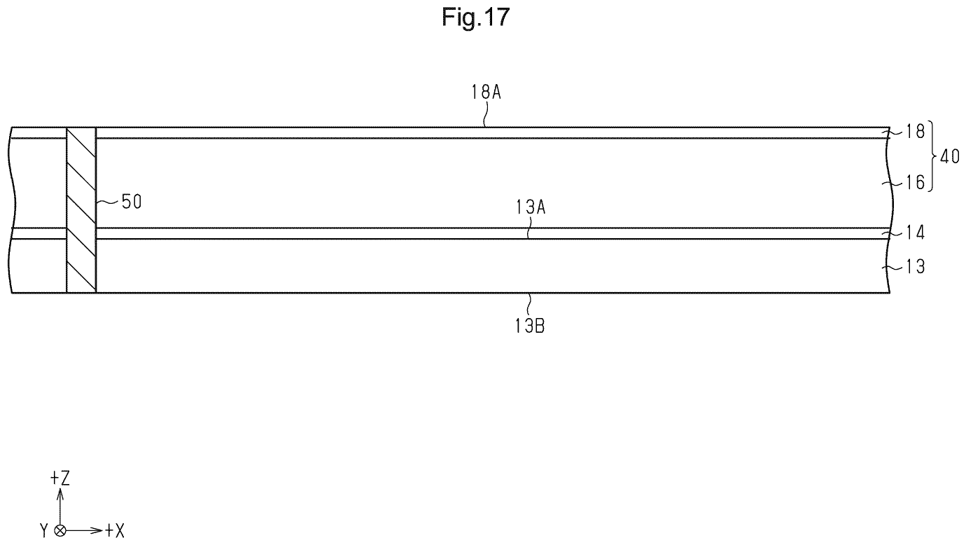

FIGS. 16 and 17 show steps performed subsequent to the step shown in FIG. 15 for forming the via 50. As shown in FIG. 16, the through hole 51 is formed to extend through the high-resistance layer 13, the buffer layer 14, and the nitride semiconductor layer 40. In this configuration, the through hole 51 may be formed from the lower surface 13B of the high-resistance layer 13 or may be formed from the upper surface of the nitride semiconductor layer 40 (the upper surface 18A of the electron supply layer 18). As shown in FIG. 17, a conductive material fills the through hole 51 to form the via 50.

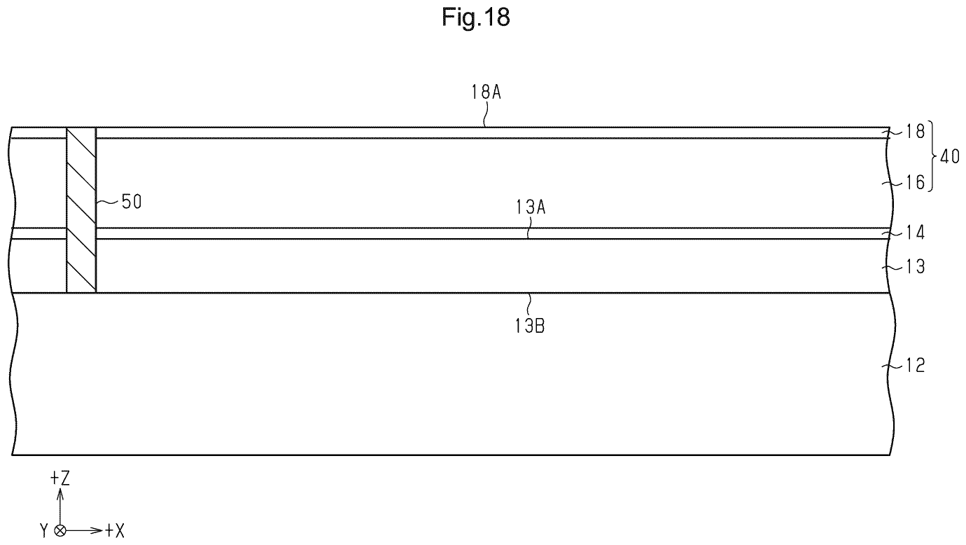

FIG. 18 is a step performed subsequent to the step shown in FIG. 17 for forming the conductive substrate 12 on the lower surface 13B of the high-resistance layer 13. Subsequent to the forming of the conductive substrate 12, the step of forming the gate layer 22, the step of forming the gate electrode 24, the step of forming the passivation layer 26, the step of forming the source electrode 28, and the step of forming the drain electrode 30 are performed as shown in FIG. 8. Alternatively, the step of forming the conductive substrate 12 may be performed subsequent to the step of forming the gate layer 22, the step of forming the gate electrode 24, the step of forming the passivation layer 26, the step of forming the source electrode 28, and the step of forming the drain electrode 30. When the conductive substrate 12 is a polycrystalline SiC substrate, it is preferred that the conductive substrate 12 is formed, and then the buffer layer 14 and the nitride semiconductor layer 40 are formed as in the description of the embodiments. This readily forms the conductive substrate 12, which is a polycrystalline SiC substrate.

In the method for manufacturing the nitride semiconductor device 10 of the first embodiment, when the via 50 and the source electrode 28 are formed of the same material, the step of filling the through hole 51 with a conductive material and the step of forming the source electrode 28 are performed as a single process.

In the method for manufacturing the nitride semiconductor device 100 of the second embodiment, the sequence of the steps may be changed. For example, the step of forming the via 500 may be performed subsequent to the step of forming the second electrode 60. Alternatively, the step of forming the second electrode 60 may be performed subsequent to the step of forming the gate layer 22, the step of forming the gate electrode 24, the step of forming the passivation layer 26, the step of forming the source electrode 28, and the step of forming the drain electrode 30.

In the method for manufacturing the nitride semiconductor device 100 of the second embodiment, when the via 500 and the source electrode 28 are formed from the same material, the step of filling the through hole 510 with a conductive material and the step of forming the source electrode 28 may be performed as a single process. Also, when the via 500 and the second electrode 60 are formed from the same material, the step of filling through hole 510 with a conductive material and the step of forming the second electrode 60 may be performed as a single process.

In the embodiments, the nitride semiconductor devices 10 and 100 is not limited to a nitride semiconductor HEMT and may be a nitride semiconductor diode.

In the present disclosure, the term “on” includes the meaning of “above” in addition to the meaning of “on” unless otherwise clearly indicated in the context. Accordingly, a phrase such as “first layer formed on second layer” may mean that the first layer is formed directly contacting the second layer in one embodiment and that the first layer is located above the second layer without contacting the second layer in another embodiment. Thus, the word “on” will also allow for a structure in which another layer is arranged between the first layer and the second layer.

The Z-direction as referred to in the present disclosure does not necessarily have to be the vertical direction and does not necessarily have to exactly coincide with the vertical direction. Accordingly, in the structures of the present disclosure, “up” and “down” in the Z-direction as referred to in this specification is not limited to “up” and “down” in the vertical direction. In an example, the X-direction may conform to the vertical direction. In another example, the Y-direction may conform to the vertical direction.

Terms such as “first,” “second,” and “third” in this disclosure are used to distinguish subjects and not used for ordinal purposes.

In this specification, “at least one of A and B” should be understood to mean “only A, or only B, or both A and B.”

### CLAUSES

Technical concepts that can be understood from each of the above embodiments and modified examples will now be described. It should be noted that, for the purpose of facilitating understanding with no intention to limit, elements described in clauses are given the reference characters of the corresponding elements of the embodiments. The reference characters are used as examples to facilitate understanding, and the elements in each clause are not limited to those elements given with the reference characters.

[Clause 1] A nitride semiconductor device (10), including:
a conductive substrate (12) including a substrate upper surface (12A);
a high-resistance layer (13) formed on the substrate upper surface (12A) and having a higher resistance value than the conductive substrate (12);
a nitride semiconductor layer (40) formed on the high-resistance layer (13);
a first electrode (28) formed on the nitride semiconductor layer (40); and
a via (50) extending through the nitride semiconductor layer (40) and the high-resistance layer (13), in which the via (50) is electrically connected to the first electrode (28) and is in contact with the substrate upper surface (12A).

[Clause 2] The nitride semiconductor device (10) according to clause 1, in which the conductive substrate (12) includes a semiconductor substrate.

[Clause 3] The nitride semiconductor device (10) according to clause 1 or 2, in which a difference in thermal expansion coefficient between the conductive substrate (12) and the high-resistance layer (13) is less than or equal to 1×10⁻⁶ (1/° C.).

[Clause 4] The nitride semiconductor device (10) according to any one of clauses 1 to 3, where
the conductive substrate (12) includes a SiC substrate, and
the high-resistance layer (13) includes a SiC layer.

[Clause 5] The nitride semiconductor device (10) according to any one of clauses 1 to 4, in which the high-resistance layer (13) is smaller in thickness than the conductive substrate (12).

[Clause 6] The nitride semiconductor device (10) according to any one of clauses 1 to 5, further including:
a buffer layer (14) arranged between the high-resistance layer (13) and the nitride semiconductor layer (40),
in which the high-resistance layer (13) has a higher resistance value than the buffer layer (14).

[Clause 7] The nitride semiconductor device (10) according to any one of clauses 1 to 6, in which the conductive substrate (12) has a resistance value that is less than or equal to 2×10⁻² Ωcm.

[Clause 8] The nitride semiconductor device (10) according to any one of clauses 1 to 7, in which the high-resistance layer (13) has a resistance value that is greater than or equal to 1×10⁵ Ωcm.

[Clause 9] A nitride semiconductor device (100), including:
a substrate (120) including a substrate upper surface (120A) and a substrate lower surface (120B) that face in opposite directions;
a high-resistance layer (130) formed on the substrate upper surface (120A) of the substrate (120) and having a higher resistance value than the substrate (120);
a nitride semiconductor layer (40) formed on the high-resistance layer (130);
a first electrode (28) formed on the nitride semiconductor layer (40);
a second electrode (60) formed on the substrate lower surface (120B) of the substrate (120); and
a via (500) extending through the nitride semiconductor layer (40), the high-resistance layer (130), and the substrate (120) and electrically connecting the first electrode (28) and the second electrode (60).

[Clause 10] The nitride semiconductor device (100) according to clause 9, in which a difference in thermal expansion coefficient between the substrate (120) and the high-resistance layer (130) is less than or equal to 1×10⁻⁶ (1/° C.).

[Clause 11] The nitride semiconductor device (100) according to clause 9 or 10, where
the substrate (120) includes a SiC substrate, and
the high-resistance layer (130) includes a SiC layer.

[Clause 12] The nitride semiconductor device (100) according to any one of clauses 9 to 11, in which the high-resistance layer (130) is greater in thickness than the substrate (120).

[Clause 13] The nitride semiconductor device (100) according to any one of clauses 9 to 12, further including:
a buffer layer (14) arranged between the high-resistance layer (130) and the nitride semiconductor layer (40),
in which the high-resistance layer (130) has a higher resistance value than the buffer layer (14).

[Clause 14] The nitride semiconductor device (100) according to any one of clauses 9 to 13, in which the high-resistance layer (130) has a resistance value that is greater than or equal to 1×10⁵ Ωcm.

[Clause 15] The nitride semiconductor device (10, 100) according to any one of clauses 1 to 14, where
the high-resistance layer (13, 130) includes an upper surface (13A, 130A) facing the nitride semiconductor layer (40),
the high-resistance layer (13, 130) includes a single-crystal SiC layer having a hexagonal crystal structure, and
the upper surface (13A, 130A) of the high-resistance layer (13, 130) is inclined with respect to a c-plane by an off-angle between 2° and 6°, inclusive.

[Clause 16] The nitride semiconductor device (10, 100) according to any one of clauses 1 to 15, where
the nitride semiconductor layer (40) includes
   an electron transit layer (16) composed of a nitride semiconductor,
   an electron supply layer (18) formed on the electron transit layer (16) and composed of a nitride semiconductor having a band gap that is larger than that of the electron transit layer (16), and
   a gate electrode (24), a source electrode (28), and a drain electrode (30) that are arranged on the electron supply layer (18), and
the via (50, 500) is electrically connected to the source electrode (28) as the first electrode.

[Clause 17] A method for manufacturing the nitride semiconductor device (10) according to any one of clauses 1 to 8, the method including:
forming the nitride semiconductor layer (40) on an upper surface (13A) of the high-resistance layer (13);
forming the via (50) in the high-resistance layer (13) and the nitride semiconductor layer (40);
forming the conductive substrate (12) on a lower surface (13B) of the high-resistance layer (13); and
forming the first electrode (28) on the nitride semiconductor layer (40).

[Clause 18] A method for manufacturing the nitride semiconductor device (100) according to any one of clauses 9 to 14, the method including:
forming the nitride semiconductor layer (40) on an upper surface (130A) of the high-resistance layer (130);
forming the substrate (120) on a lower surface (130B) of the high-resistance layer (130);
forming the via (500) in the substrate (120), the high-resistance layer (130), and the nitride semiconductor layer (40);
forming the second electrode (60) on the substrate lower surface (120B) of the substrate (120); and
forming the first electrode (28) on the nitride semiconductor layer (40).

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
a conductive substrate including a substrate upper surface;
a high-resistance layer formed on the substrate upper surface and having a higher resistance value than the conductive substrate;
a nitride semiconductor layer formed on the high-resistance layer;
a first electrode formed on the nitride semiconductor layer; and
a via extending through the nitride semiconductor layer and the high-resistance layer, wherein the via is electrically connected to the first electrode and is in contact with the substrate upper surface.

2. The nitride semiconductor device according to claim 1, wherein the conductive substrate includes a semiconductor substrate.

3. The nitride semiconductor device according to claim 1, wherein a difference in thermal expansion coefficient between the conductive substrate and the high-resistance layer is less than or equal to 1×10⁻⁶ (1/° C.).

4. The nitride semiconductor device according to claim 1, wherein
the conductive substrate includes a SiC substrate, and
the high-resistance layer includes a SiC layer.

5. The nitride semiconductor device according to claim 1, wherein the high-resistance layer is smaller in thickness than the conductive substrate.

6. The nitride semiconductor device according to claim 1, further comprising:
a buffer layer arranged between the high-resistance layer and the nitride semiconductor layer,
wherein the high-resistance layer has a higher resistance value than the buffer layer.

7. The nitride semiconductor device according to claim 1, wherein the conductive substrate has a resistance value that is less than or equal to 2×10⁻² Ωcm.

8. The nitride semiconductor device according to claim 1, wherein the high-resistance layer has a resistance value that is greater than or equal to 1×10⁵ Ωcm.

9. A nitride semiconductor device, comprising:
a substrate including a substrate upper surface and a substrate lower surface that face in opposite directions;
a high-resistance layer formed on the substrate upper surface of the substrate and having a higher resistance value than the substrate;
a nitride semiconductor layer formed on the high-resistance layer;
a first electrode formed on the nitride semiconductor layer;
a second electrode formed on the substrate lower surface of the substrate; and
a via extending through the nitride semiconductor layer, the high-resistance layer, and the substrate and electrically connecting the first electrode and the second electrode.

10. The nitride semiconductor device according to claim 9, wherein a difference in thermal expansion coefficient between the substrate and the high-resistance layer is less than or equal to 1×10⁻⁶ (1/° C.).

11. The nitride semiconductor device according to claim 9, wherein
the substrate includes a SiC substrate, and
the high-resistance layer includes a SiC layer.

12. The nitride semiconductor device according to claim 9, wherein the high-resistance layer is greater in thickness than the substrate.

13. The nitride semiconductor device according to claim 9, further comprising:
a buffer layer arranged between the high-resistance layer and the nitride semiconductor layer,
wherein the high-resistance layer has a higher resistance value than the buffer layer.

14. The nitride semiconductor device according to claim 9, wherein the high-resistance layer has a resistance value that is greater than or equal to 1×10⁵ Ωcm.

15. The nitride semiconductor device according to claim 1, wherein
the high-resistance layer includes an upper surface facing the nitride semiconductor layer,
the high-resistance layer includes a single-crystal SiC layer having a hexagonal crystal structure, and
the upper surface of the high-resistance layer is inclined with respect to a c-plane by an off-angle between 2° and 6°, inclusive.

16. The nitride semiconductor device according to claim 1, wherein
the nitride semiconductor layer includes
an electron transit layer composed of a nitride semiconductor,
an electron supply layer formed on the electron transit layer and composed of a nitride semiconductor having a band gap that is larger than that of the electron transit layer, and
a gate electrode, a source electrode, and a drain electrode that are arranged on the electron supply layer, and
the via is electrically connected to the source electrode as the first electrode.
